(19) United States
(12) Patent Application Publication
(10) Pub. No.: US 2018/0135922 A1
(43) Pub. Date: May 17, 2018

(54) HEAT DISSIPATION STRUCTURAL MEMBER HAVING GOOD COMPREHENSIVE PERFORMANCE AND PREPARATION PROCESS THEREOF

(71) Applicant: Chintung Lin, Xinbei (TW)

(72) Inventor: Chintung Lin, Xinbei (TW)

(21) Appl. No.: 15/803,347

(22) Filed: Nov. 3, 2017

(30) Foreign Application Priority Data
Nov. 16, 2016 (CN) 201611009301.6

(51) Int. Cl. F28F 3/04; F28F 13/18; F28F 19/06; H01L 23/373

(52) U.S. Cl. CPC F28F 3/048; F28F 13/185; H01L 23/3677; H01L 23/3735; F28F 19/06

(57) ABSTRACT

A heat dissipation structural member having a good comprehensive performance, comprising plate A, plate B, capillary function layers and a cooling liquid; a plurality of copper columns that are disposed on the inner surface of plate A and abut against plate A is soldered to the inner surface of plate A through the outer surface of plate A; plate B and plate A are assembled in a sealed manner; plate B is provided with a groove corresponding to the copper columns of plate A; the copper columns of plate A abut against the inner surface of the groove of plate B, and the copper columns abutting against plate B are soldered to the inner surface of plate B through the outer surface of plate B.

### TECHNICAL FIELD OF THE INVENTION

The present invention relates to the technical field of electronic product heat dissipation, and more particularly, to a heat dissipation structural member having a good comprehensive performance and a preparation process thereof.

### BACKGROUND OF THE INVENTION

Heat dissipation performance plays a key role in guaranteeing that electronic products work effectively. A multi-layer sheet-type heat sink made from aluminum or copper is usually adopted in an electronic product to dissipate heat. Some large-sized products also adopt a cooling heat dissipation method to dissipate heat through water or other cooling liquids. As electronic products are gradually miniaturized, the heat dissipation device must be also be smaller.

In the prior art, a traditional heat dissipation device having a small size and a good heat dissipation performance is provided with a cavity that is formed by two base plates. A capillary function layer, which is made from metal powder having a rough surface structure, is provided on the inner wall of each base plate. Additionally, a cooling liquid is filled between the two base plates in a sealed manner. The capillary function layer is usually made from copper powder, through which the cooling liquid can be absorbed by the gaps in the copper powder at a normal temperature. When the heating element generates heat, the copper powder in the cavity can be discharged due to the capillary phenomenon, thereby pushing the cooling liquid to move. As a result, a pushing force for pushing the cooling liquid to move in the cavity is generated, promoting the cooling liquid to flow so that the heat can be transferred in time. In order to ensure the existence of the cavity, copper columns are provided between the base plates to support therein, and one of the base plates is provided with a groove structure.

During the traditional manufacturing process, copper columns and base plates are sintered together to form an integral structure. Thus, the copper columns need to be sintered for about 1 hour at a temperature of 900° C. before being treated by tempering and other steps. Consequently, the copper columns are not hard enough. Besides, the heat dissipation device having such a structure is poor in explosion resistance, pressure resistance, flatness and glossiness. Furthermore, the traditional preparation process comprises sintering, tempering and other steps, which is time-consuming, energy-consuming, material-wasting and environment-polluting.

Thus, it's urgent for those skilled in this field to provide a heat dissipation structural member having a good comprehensive performance and a preparation process thereof to overcome the shortcomings in the prior art.

### SUMMARY OF THE INVENTION

The purpose of the present invention is to solve the shortcomings in the prior art and provide a heat dissipation structural member having a good comprehensive performance, which can be conveniently prepared without being sintered and tempered, and is excellent in hardness, explosion resistance, pressure resistance, flatness and glossiness.

To achieve the above purpose, the present invention adopts the following technical solution:

A heat dissipation structural member having a good comprehensive performance, comprising plate A, plate B, capillary function layers and a cooling liquid; a plurality of copper columns that are disposed on the inner surface of plate A and abut against plate A is soldered to the inner surface of plate A through the outer surface of plate A; plate B and plate A are assembled in a sealed manner; plate B is provided with a groove corresponding to the copper columns of plate A; the copper columns of plate A abut against the inner surface of the groove of plate B, and the copper columns abutting against plate B are soldered to the inner surface of plate B through the outer surface of plate B; the inner surfaces of plate A and plate B are respectively provided with a capillary function layer; the cooling liquid is filled in the cavity formed by plate A and plate B; the interior of the cavity is in a vacuum state.

In another preferred embodiment, plate A is a plane structure.

In another preferred embodiment, plate B is provided with a cooling liquid feeding channel that is connected to the groove. The cooling liquid feeding channel is flattened after the cooling liquid is fed into the channel and the cavity is vacuumed, and then is connected to plate A in a sealed manner.

In another preferred embodiment, the copper columns are uniformly or non-uniformly distributed in the corresponding area of the inner surface of plate A.

In another preferred embodiment, the outer surface of plate B is provided with a soldering route. The soldering route is a circle of edge line that is formed when the groove protrudes from the outer surface of plate B.

A process for preparing the aforesaid heat dissipation structural member having a good comprehensive performance, comprising the steps of:

Step 1: placing the copper columns in a mold and then placing plate A above the copper columns; subsequently, soldering on one side of plate A that is far from the copper columns through a soldering apparatus, thereby fixing the copper columns abutting against the inner surface of plate A to the inner surface of plate A;

Step 2: separately preparing the capillary function layers of plate A and plate B; subsequently, respectively depositing the capillary function layers to the corresponding positions of plate A and plate B;

Step 3: assembling plate B to plate A, wherein the inner surface of the groove of plate B abuts against the copper columns that are soldered to plate A; subsequently, soldering plate B to the copper columns through the outer surface of plate B;

Step 4: seal-soldering the periphery of plate B and plate A, thereby forming the cavity structure;

Step 5: feeding cooling liquid into the cavity formed by plate A and plate B after plate A and plate B are seal-soldered; subsequently, vacuuming the cavity and sealing the cooling liquid feeding channel.

In another preferred embodiment, the soldering method is either a laser soldering method or an electron beam soldering method.

In another preferred embodiment, both plate A and plate B are copper plates, and the capillary function layers are made from copper powder.

In another preferred embodiment, to seal-solder plate B and plate A in step 4 is to solder along the soldering route provided on the outer surface of plate B.

To seal the cooling liquid feeding channel in step 5, flatten the cooling liquid feeding channel provided on plate B after the cooling liquid is fed into the channel and the cavity is vacuumed, and then seal the flattened cooling liquid feeding channel with plate A by means of a riveting method.

In another preferred embodiment, the aforesaid process for preparing the heat dissipation structural member having a good comprehensive performance further comprises:

Step 6: separately grinding the outer surfaces of plate A and plate B.

Compared with the prior art, the present invention has the following advantages:

The present invention provides a heat dissipation structural member having a good comprehensive performance and a preparation process thereof, wherein a plurality of copper columns that are disposed on the inner surface of plate A and abut against plate A is soldered to the inner surface of plate A through the outer surface of plate A, and the copper columns abutting against plate B is soldered to the inner surface of plate B through the outer surface of plate B. Thus, the sintering and tempering steps in the traditional process can be saved so that the hardness of plate A, plate B and the copper columns are perfectly maintained. Therefore, the heat dissipation structural member of the present invention has excellent hardness, explosion resistance and pressure resistance. Meanwhile, due to the simplified preparation process, the processing time is significantly reduced. The prepared heat dissipation structural member has good flatness and glossiness.

### BRIEF DESCRIPTION OF THE DRAWINGS

To clearly expound the present invention or technical solution, the drawings and embodiments are hereinafter combined to illustrate the present invention. Obviously, the drawings are merely some embodiments of the present invention and those skilled in the art can associate themselves with other drawings without paying creative labor.

FIG. 1 is a sectional view of the heat dissipation structural member having a good comprehensive performance of the present invention;

FIG. 2 is a structural diagram of the inner surface of plate A of the heat dissipation structural member having a good comprehensive performance of the present invention;

FIG. 3 is a structural diagram of the inner surface of plate B of the heat dissipation structural member having a good comprehensive performance of the present invention; and

FIG. 4 is a structural diagram of the outer surface of plate B of the heat dissipation structural member having a good comprehensive performance of the present invention;

### Marking Instructions of the Drawings:

Plate A 100, Copper Column 110, Plate B 200, Groove 210, Cooling Liquid Feeding Channel 220, Soldering Route 230, Capillary Function Layer 300, Cavity 400

### DETAILED DESCRIPTION OF THE INVENTION

Drawings and detailed embodiments are combined hereinafter to elaborate the technical principles of the present invention.

### Embodiment 1

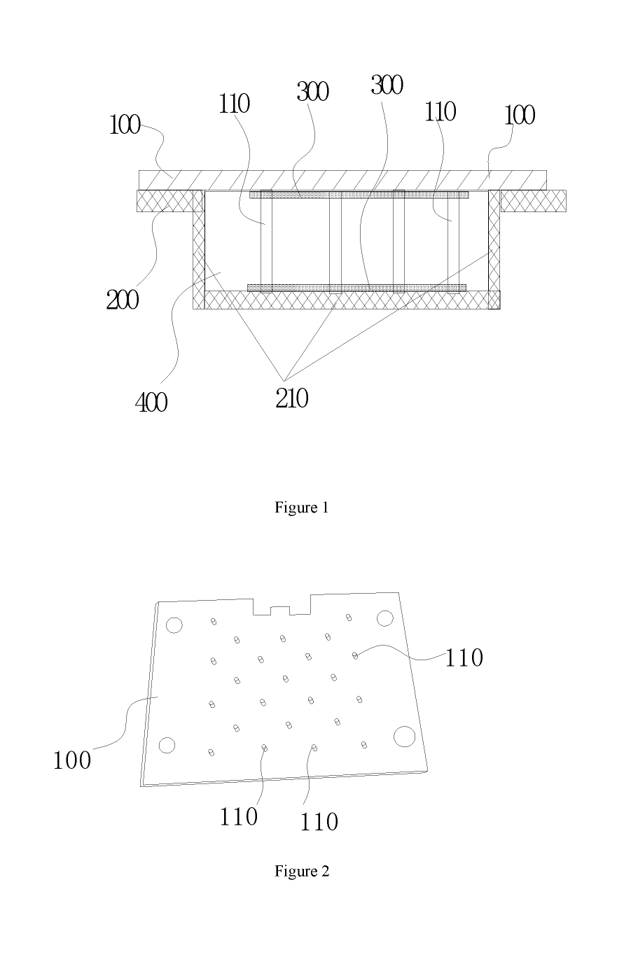

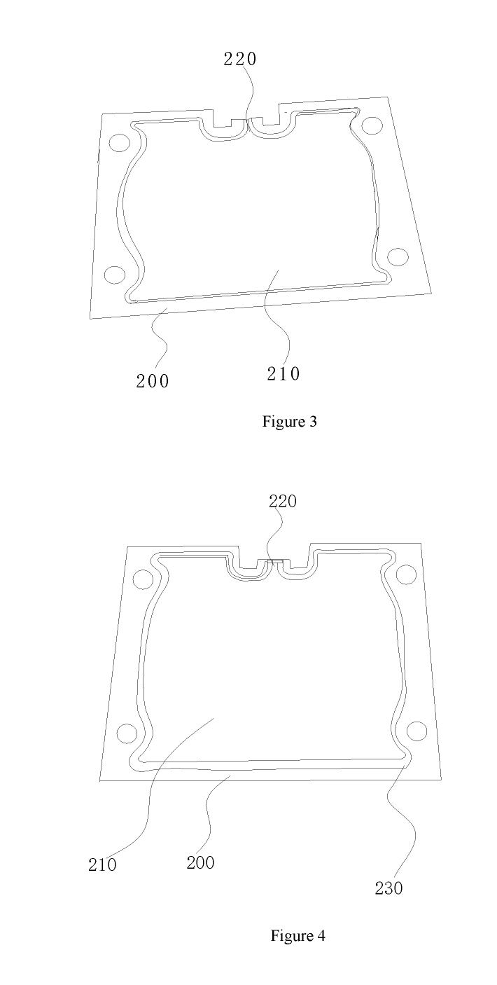

This embodiment provides a heat dissipation structural member having a good comprehensive performance. As shown in FIGS. 1 and 2, the heat dissipation structural member comprises plate A 100, plate B 200, capillary function layers 300 and a cooling liquid.

A plurality of copper columns 110 that are disposed on the inner surface of plate A 100 and abut against plate A 100 is soldered to the inner surface of plate A 100 through the outer surface of plate A 100.

Plate B 200 and plate A 100 are assembled in a sealed manner. Plate B 200 is provided with a groove 210 corresponding to the copper columns 110 of plate A 100. The copper columns 110 of plate A 100 abut against the inner surface of the groove 210 of plate B 200, and the copper columns 110 abutting against plate B 200 are soldered to the inner surface of plate B 200 through the outer surface of plate B 200. Plate A 100 is assembled to plate B 200, and the two ends of the copper columns are respectively connected to plate A 100 and plate B 200. The cavity 400 is formed between plate A 100 and plate B 200.

The inner surfaces of plate A and plate B are respectively provided with a capillary function layer 300.

The cooling liquid is filled in the cavity 400 formed by plate A 100 and plate B 200. The interior of the cavity 400 is in a vacuum state, and the cavity 400 is filled with the cooling liquid. The gaps in the capillary function layers 300 can absorb the cooling liquid at a normal temperature. When the heat dissipation member is heated, the metal powder in the cavity 400 can be discharged due to the capillary phenomenon, thereby pushing the cooling liquid to move. Thus, a pushing force capable of pushing the cooling liquid in the cavity to move is formed, promoting the cooling liquid to flow so that the heat can be transferred in time.

In this embodiment, plate A 100 is a plane plate. A plurality of copper columns 110 is uniformly distributed in the corresponding area of the inner surface of plate A 100. Correspondingly, plate B 200 that is assembled to plate A 100 is provided with a groove 210. Copper columns 110 are utilized to support between plate A 100 and plate B 200, thereby ensuring the existence of the cavity 400. Plate A and plate B are preferred to be copper plates so that a good heat dissipation performance can be achieved.

It should be noted that plate A 100 can be a plane plate having various structures. The plurality of copper columns 110 can either be uniformly or non-uniformly distributed on the inner surface of plate A 100.

As the copper columns 110 that are disposed on the inner surface of plate A 100 and abut against plate A 100 are soldered to the inner surface of plate A 100 through the outer surface of plate A 100, and the copper columns 110 abutting against plate B 200 are soldered to the inner surface of plate B 200 through the outer surface of plate B 200, the copper columns 110 are prevented from being sintered with plate A100 and plate B200 into an integral body. Therefore, the high-temperature sintering and tempering steps in the prior art can be avoided, and this effectively protects the hardness of plate A and plate B. Thus, the heat dissipation structural member of the present invention has excellent hardness, explosion resistance and pressure resistance. Meanwhile, due to the simplified preparation process, the processing time is significantly reduced. The prepared heat dissipation structural member of the present invention has good flatness and glossiness.

Plate B 200 is provided with a cooling liquid feeding channel 220 that is connected to the groove 210. The cooling liquid feeding channel 220 is flattened after the cooling liquid is fed into the channel 220 and the cavity 400 is vacuumed, and then is connected to plate A 100 in a sealed manner.

In such a configuration, it's unnecessary to provide a separate cooling liquid connecting channel, or seal the cooling liquid connecting channel after the cooling liquid is filled and the channel is vacuumed. It is found in practice that the cooling liquid connecting channel and the gas connecting channel can easily cause leakage due to various reasons, thereby leading to the failure of the heat dissipation device. As a result, the heat dissipation structural member of the present invention is free of any cooling liquid connecting channel and gas connecting channel. In the present invention, the cooling liquid feeding channel provided on plate B 200 is flattened after the cooling liquid is fed into the channel and the cavity is vacuumed, and then is sealed with plate A 100 by means of a riveting method. In such a way, the risk of leaking during use can be greatly reduced, and the functional life of the heat dissipation structural member can be ensured.

The outer surface of plate B 200 is provided with a soldering route 230. The soldering route 230 is a circle of edge line that is formed when the groove 210 protrudes from the outer surface of plate B 200. When plate B 200 is soldered to the copper columns 110, the periphery of the cavity 400 formed by plate A 100 and plate B 200 is seal-soldered along the soldering route, which can be conveniently operated by the user.

The heat dissipation structural member of the present invention adopts a soldering method to separately solder the copper columns 110 to plate A 100 and plate B 200, and then seal-solder plate A 100 and plate B into an integral structure. The preparation process can be completed within 5-20 seconds. Compared with the traditional process that costs 1-2 hours, the preparation process of the present invention can greatly improve the production efficiency.

The process for preparing the aforesaid heat dissipation structural member having a good comprehensive performance, comprising the steps of:

Step 1: placing the copper columns 110 in a mold and then placing plate A 100 above the copper columns 110; subsequently, soldering on one side of plate A 100 that is far from the copper columns 110 through a soldering apparatus, thereby fixing the copper columns 110 abutting against the inner surface of plate A to the inner surface of plate A;

Step 2: separately preparing the capillary function layers 300 of plate A 100 and plate B 200; subsequently, respectively depositing the capillary function layers 300 to the corresponding positions of plate A 100 and plate B 200;

Step 3: assembling plate B 200 to plate A 100, wherein the inner surface of the groove 210 of plate B 200 abuts against the copper columns 110 that are soldered to plate A 100; subsequently, soldering plate B 200 to the copper columns 110 through the outer surface of plate B 200;

Step 4: seal-soldering the periphery of plate B 200 and plate A 100, thereby forming the cavity 400; specifically, to seal-solder the periphery of plate B 200 and plate A 100, solder along the soldering route 230 provided on the outer surface of plate B 200;

Step 5: feeding the cooling liquid into the cavity 400 formed by plate A 100 and plate B 200 after plate A 100 and plate B 200 are seal-soldered; subsequently, vacuuming the cavity 400 and sealing the cooling liquid feeding channel 220; specifically, to seal the cooling liquid feeding channel 220 is first to flatten the cooling liquid feeding channel 220 provided on plate B after the cooling liquid is fed into the channel 220 and the cavity 400 is vacuumed, and then to seal the flattened cooling liquid feeding channel 220 with plate A 100 by means of a riveting method;

Step 6: separately grinding the outer surfaces of plate A 100 and plate B 200, thus protecting other components that are in contact with plate A 100 and plate B 200 from being scratched.

In another preferred embodiment, the soldering method is either a laser soldering method or an electron beam soldering method.

In another preferred embodiment, both plate A 100 and plate B 200 are copper plates, and the capillary function layers 300 are made from copper powder.

The heat dissipation structural member of the present invention adopts a soldering method to separately solder the copper columns 110 to plate A 100 and plate B 200, and then seal-solder plate A 100 and plate B into an integral structure. The preparation process can be completed within 5-20 seconds. Compared with the traditional process that costs 1-2 hours, the preparation process of the present invention can greatly improve production efficiency.

In conclusion, the prepared heat dissipation structural member of the present invention is excellent in hardness, explosion resistance and pressure resistance, and has good flatness and glossiness. Meanwhile, due to the simplified preparation process, the processing time is significantly reduced.

The description of above embodiments allows those skilled in the art to realize or use the present invention. Without departing from the spirit and essence of the present invention, those skilled in the art can combine, change or modify correspondingly according to the present invention. Therefore, the protective range of the present invention should not be limited to the embodiments above but conform to the widest protective range which is consistent with the principles and innovative characteristics of the present invention. Although some special terms are used in the description of the present invention, the scope of the invention should not necessarily be limited by this description. The scope of the present invention is defined by the claims.

1. A heat dissipation structural member having a good comprehensive performance, comprising:
plate A,
plate B,
capillary function layers, and
a cooling liquid, wherein a plurality of copper columns that are disposed on the inner surface of plate A and abut against plate A is soldered to the inner surface of plate A through the outer surface of plate A, wherein plate B and plate A are assembled in a sealed manner, wherein plate B is provided with a groove corresponding to the copper columns of plate A, wherein the copper columns of plate A abut against the inner surface of the groove of plate B, and the copper columns abutting against plate B are soldered to the inner surface of plate B through the outer surface of plate B, wherein the inner surfaces of plate A and plate B are respectively provided with a capillary function layer, wherein the cooling liquid is filled in the cavity formed by plate A and plate B, wherein the interior of the cavity is in a vacuum state.

2. The heat dissipation structural member having a good comprehensive performance of claim 1, wherein plate A is a plane structure.

3. The heat dissipation structural member having a good comprehensive performance of claim 2, wherein plate B is provided with a cooling liquid feeding channel that is connected to the groove, wherein the cooling liquid feeding channel is flattened after the cooling liquid is fed into the channel and the cavity is vacuumed, and then is connected to plate A in a sealed manner.

4. The heat dissipation structural member having a good comprehensive performance of claim 3, wherein the copper columns are uniformly or non-uniformly distributed in the corresponding area of the inner surface of plate A.

5. The heat dissipation structural member having a good comprehensive performance of claim 4, wherein the outer surface of plate B is provided with a soldering route, wherein the soldering route is a circle of edge line that is formed when the groove protrudes from the outer surface of plate B.

6. A process for preparing the heat dissipation structural member having a good comprehensive performance of claim 5, comprising the steps of:
Step 1: placing the copper columns in a mold and then placing plate A above the copper columns; subsequently, soldering on one side of plate A that is far from the copper columns through a soldering apparatus, thereby fixing the copper columns abutting against the inner surface of plate A to the inner surface of plate A;
Step 2: separately preparing the capillary function layers of plate A and plate B; subsequently, respectively depositing the capillary function layers to the corresponding positions of plate A and plate B;
Step 3: assembling plate B to plate A, wherein the inner surface of the groove of plate B abuts against the copper columns that are soldered to plate A; subsequently, soldering plate B to the copper columns through the outer surface of plate B;
Step 4: seal-soldering the periphery of plate B and plate A, thereby forming the cavity structure;
Step 5: feeding cooling liquid into the cavity formed by plate A and plate B after plate A and plate B are seal-soldered; subsequently, vacuuming the cavity and sealing the cooling liquid feeding channel.

7. The heat dissipation structural member having a good comprehensive performance of claim 6, wherein the soldering method is either a laser soldering method or an electron beam soldering method.

8. The heat dissipation structural member having a good comprehensive performance of claim 8, wherein both plate A and plate B are copper plates, and the capillary function layers are made from copper powder.

9. The heat dissipation structural member having a good comprehensive performance of claim 8, wherein to seal-solder plate B and plate A in step 4 is to solder along the soldering route provided on the outer surface of plate B, wherein
to seal the cooling liquid feeding channel in step 5 is first to flatten the cooling liquid feeding channel provided on plate B after the cooling liquid is fed into the channel and the cavity is vacuumed, and then to seal the flattened cooling liquid feeding channel with plate A by means of a riveting method.

10. The process for preparing the heat dissipation structural member having a good comprehensive performance of claim 9, further comprising:
Step 6: separately grinding the outer surfaces of plate A and plate B.
